(19) United States
(12) Patent Application Publication
(10) Pub. No.: US 2024/0258389 A1
(43) Pub. Date: Aug. 1, 2024

(54) SEMICONDUCTOR DEVICE

(71) Applicant: ROHM CO., LTD., Kyoto-shi (JP)

(72) Inventors: Manabu YANAGIHARA, Kyoto-shi (JP); Hirotaka OTAKE, Kyoto-shi (JP)

(73) Assignee: ROHM CO., LTD., Kyoto-shi (JP)

(21) Appl. No.: 18/592,594

(22) Filed: Mar. 1, 2024

Related U.S. Application Data
(63) Continuation of application No. PCT/JP2022/031873, filed on Aug. 24, 2022.

(30) Foreign Application Priority Data
Sep. 14, 2021 (JP) 2021-149205

(51) Int. Cl. H01L 29/417; H01L 29/06; H01L 29/20; H01L 29/778

(52) U.S. Cl. CPC H01L 29/41758; H01L 29/0692; H01L 29/2003; H01L 29/7787

(57) ABSTRACT

A semiconductor device includes a first semiconductor and a second semiconductor layer arranged thereon to generate a 2DEG in the first semiconductor layer. A source electrode and a drain electrode are arranged on the second semiconductor layer. A third semiconductor layer including an acceptor impurity is arranged on the second semiconductor layer between the source electrode and the drain electrode. A gate electrode is arranged on the third semiconductor layer. The second semiconductor layer defines a boundary between an element region including an FET and an element separation region. A guard ring is arranged on the second semiconductor layer in a peripheral part of the element region. The guard ring includes a fourth semiconductor layer arranged on the second semiconductor layer and including an acceptor impurity and a first electrode arranged on the fourth semiconductor layer and electrically connected to the source electrode or the 2GEG.

### CROSS-REFERENCE TO RELATED APPLICATIONS

This application is a continuation of International Application No. PCT/JP2022/031873, filed Aug. 24, 2022, which claims priority to Japanese Patent Application No. 2021-149205, filed Sep. 14, 2021, the entire contents of each are incorporated herein by reference.

### BACKGROUND

### 1. Field

The following description relates to a semiconductor device.

### 2. Description of Related Art

A group III-V semiconductor such as gallium nitride (GaN) is currently used to produce a high-electron-mobility transistor (HEMT). In the HEMT, a two-dimensional electron gas (2DEG) is formed in the vicinity of a semiconductor heterojunction interface and is used as a conductive path (channel). It is recognized that a power device that uses the HEMT is capable of performing a high-speed, high-frequency operation with a low on-resistance as compared to a typical silicon (Si) power device.

The gate capacity of the HEMT is relatively small, so that the element may fail to sufficiently absorb surge caused by static electricity or the like. When the transistor has a low resistance to surge, surge may adversely affect the properties of the transistor by, for example, increasing on-resistance and decreasing breakdown voltage.

Japanese Laid-Open Patent Publication No. 2013-201262 discloses that a guard ring formation region for shielding against static electricity is arranged around an element region to increase resistance to static electricity. Japanese Laid-Open Patent Publication No. 2013-201262 discloses a structure in which 2DEG is formed in a carrier transit layer that forms a heterojunction with a barrier layer, and the 2DEG is in ohmic contact with an electrode (shield layer) arranged on the barrier layer in the guard ring formation region. In this structure, the shield layer and the 2DEG that is present immediately below the shield layer are used as a shield against static electricity.

In the structure described above in the publication, isolation regions that are free of the 2DEG need to be formed at opposite sides of the shield layer by eliminating the 2DEG from the entire perimeter of the guard ring formation region, which surrounds the element region, except for the portion of the 2DEG that is present immediately below the shield layer. The guard ring formation region (the shield layer and the isolation regions located at opposite sides of the shield layer) needs to have a relatively large area in order to obtain a sufficient surge resistance.

However, a reduction in the chip area for downsizing the transistor may result in an insufficient area for the guard ring formation region. Therefore, as described above, the structure using the shield layer (guard ring formation region) imposes limitations on an increase in surge resistance.

### BRIEF DESCRIPTION OF THE DRAWINGS

FIG. 1 is a schematic plan view showing an exemplary semiconductor device according to a first embodiment.

FIG. 2 is a schematic cross-sectional view taken along line F2-F2 in FIG. 1.

FIG. 3 is a schematic plan view of the semiconductor device shown in FIG. 1 having an exemplary wiring structure.

FIG. 4 is a schematic cross-sectional view taken along line F4-F4 in FIG. 3.

FIG. 5 is a schematic cross-sectional view of an exemplary guard ring according to a second embodiment.

FIG. 6 is a schematic cross-sectional view of an exemplary guard ring according to a third embodiment.

FIG. 7 is a schematic cross-sectional view of an exemplary guard ring according to a fourth embodiment.

FIG. 8 is a schematic cross-sectional view of an exemplary guard ring according to a fifth embodiment.

Throughout the drawings and the detailed description, the same reference numerals refer to the same elements. The drawings may not be to scale, and the relative size, proportions, and depiction of elements in the drawings may be exaggerated for clarity, illustration, and convenience. In a cross-sectional view, hatching may be omitted to facilitate understanding.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

### First Embodiment

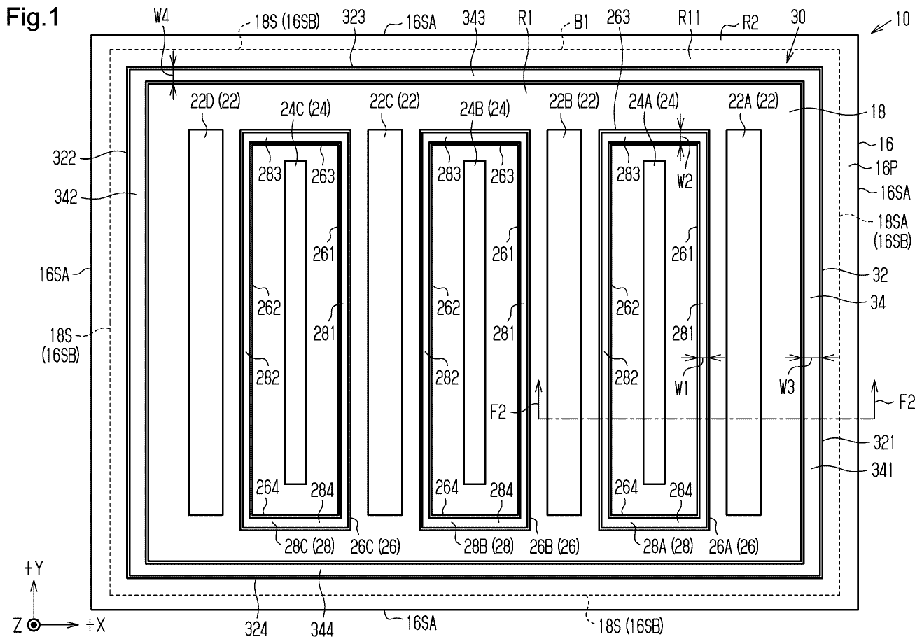

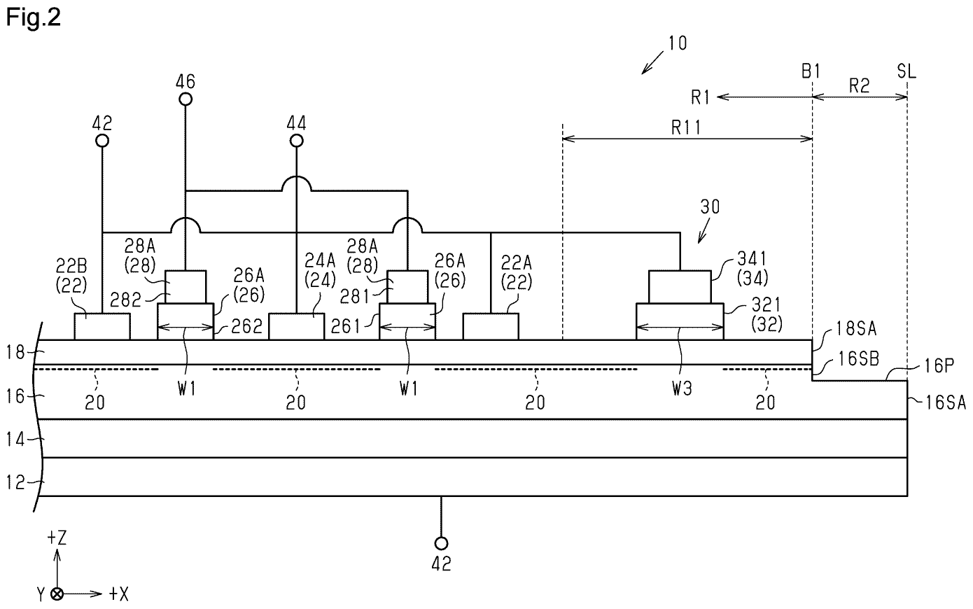

FIG. 1 is a schematic plan view showing an exemplary semiconductor device 10 according to a first embodiment. FIG. 2 is a schematic cross-sectional view taken along line F2-F2 in FIG. 1. The semiconductor device 10 may be configured as a field-effect transistor (FET) that uses a compound semiconductor. In an example, the semiconductor device 10 may be configured as a high-electron-mobility transistor (HEMT) that uses a nitride semiconductor such as gallium nitride (GaN).

As shown in FIG. 2, the semiconductor device 10 includes a substrate 12, a buffer layer 14 formed on the substrate 12, an electron transit layer 16 formed on the buffer layer 14, and an electron supply layer 18 formed on the electron transit layer 16. The electron transit layer 16 is an example of a first semiconductor layer. The electron supply layer 18 is an example of a second semiconductor layer.

The substrate 12 may be formed from silicon (Si), silicon carbide (SiC), GaN, sapphire, or other substrate materials. In an example, the substrate 12 is a conductive Si substrate. The substrate 12 may have a thickness that is, for example, greater than or equal to 200 μm and less than or equal to 1500 μm. The substrate 12 is, for example, rectangular in plan view.

Unless otherwise specifically described, the term “plan view” used in the present disclosure refers to a view of an object (the semiconductor device 10 or its components) in a Z-direction when XYZ-axes are orthogonal to each other. In the present disclosure, the Z-direction refers to a direction orthogonal to a surface of the substrate 12 on which the electron transit layer 16 is formed (for example, via the buffer layer 14). In the following description, to facilitate understanding, the +Z direction defines the upper side, and the −Z direction defines the lower side. The +X direction defines the right, and the −X direction defines the left.

The buffer layer 14 may be arranged between the substrate 12 and the electron transit layer 16 and be formed of any material that reduces lattice mismatching between the substrate 12 and the electron transit layer 16. The buffer layer 14 may include one or more nitride semiconductor layers. In an example, the buffer layer 14 may include at least one of an aluminum nitride (AlN) layer, an aluminum gallium nitride (AlGaN) layer, and a graded AlGaN layer having different aluminum (Al) compositions. In an example, the buffer layer 14 may be formed of a single AlN layer, a single AlGaN layer, a layer having a superlattice structure of AlGaN/GaN, a layer having a superlattice structure of AlN/AlGaN, or a layer having a superlattice structure of AlN/GaN.

In an example, the buffer layer 14 includes a first buffer layer formed on the substrate 12 and a second buffer layer formed on the first buffer layer. In an example, the first buffer layer may be an AlN layer having a thickness of 200 nm. In an example, the second buffer layer may be multiple AlGaN layers, each of which has a thickness of 100 nm. To inhibit current leakage of the buffer layer 14, the buffer layer 14 may be partially doped with an impurity so that the buffer layer 14 becomes semi-insulating. In this case, the impurity may be, for example, carbon (C) or iron (Fe). The concentration of the impurity may be, for example, greater than or equal to 4×10¹⁶ cm⁻³.

The buffer layer 14 is, for example, rectangular in plan view. In an example, the buffer layer 14 is the same size in plan view as the substrate 12 and covers the entirety of the main surface (upper surface in FIG. 2) of the substrate 12.

The electron transit layer 16 may be formed of a nitride semiconductor. In an example, the electron transit layer 16 may be a GaN layer. The electron transit layer 16 may have a thickness that is, for example, greater than or equal to 0.1 μm and less than or equal to 2 μm. To inhibit current leakage of the electron transit layer 16, the electron transit layer 16 may be partially doped with an impurity so that the electron transit layer 16 excluding its surface region becomes semi-insulating. In this case, the impurity is, for example, C. The concentration of the impurity may be, for example, greater than or equal to 4×10¹⁹ cm⁻³ at a peak concentration.

The electron transit layer 16 is, for example, rectangular in plan view. In an example, the electron transit layer 16 is the same size in plan view as the substrate 12 and the buffer layer 14 and covers the entirety of the main surface (upper surface in FIG. 2) of the buffer layer 14.

The electron supply layer 18 may be formed of a nitride semiconductor. In an example, the electron supply layer 18 may be an AlGaN layer. In the AlGaN layer, the bandgap becomes larger as the Al composition increases. Therefore, the electron supply layer 18, which is an AlGaN layer, has a larger band gap than the electron transit layer 16, which is a GaN layer. In an example, the electron supply layer 18 is composed of AlₓGa₁₋ₓN, where 0.1<x<0.4, and, more preferably, 0.2<x<0.3. However, the range of x is not limited to these. The electron supply layer 18 may have a thickness that is, for example, greater than or equal to 5 nm and less than or equal to 20 nm.

The electron transit layer 16 and the electron supply layer 18 are each composed of a nitride semiconductor having a different lattice constant. Thus, the nitride semiconductor of the electron transit layer 16 (e.g., GaN) and the nitride semiconductor of the electron supply layer 18 (e.g., AlGaN) form a lattice-mismatching junction. In the vicinity of the heterojunction interface between the electron transit layer 16 and the electron supply layer 18, the energy level in the conduction band of the electron transit layer 16 is lower than the Fermi level due to spontaneous polarization of the electron transit layer 16 and the electron supply layer 18 and piezoelectric polarization caused by stress received by the heterojunction of the electron supply layer 18. As a result, at a location close to the heterojunction interface between the electron transit layer 16 and the electron supply layer 18 (for example, approximately a few nanometers away from the interface), two-dimensional electron gas 20 (2DEG) spreads in the electron transit layer 16.

The electron supply layer 18 is, for example, rectangular in plan view. In an example, the electron supply layer 18 is smaller in size in plan view than the electron transit layer 16. The electron supply layer 18 defines a boundary B1 between an element region R1, in which an FET is formed, and an element separation region R2, which surrounds the element region R1. In other words, the electron supply layer 18 defines the area of the element region R1.

In the present disclosure, the element region R1 refers to a region including an active region that mainly includes a transistor structure contributing to operation of the FET (in the example shown in FIGS. 1 and 2, HEMT).

As shown in FIGS. 1 and 2, the electron supply layer 18 includes a peripheral side surface 18SA, which defines an outer border of the element region R1. The peripheral side surface 18SA is located on the boundary B1 of the element region R1 and the element separation region R2. Thus, the electron supply layer 18 is not present in the element separation region R2. In an example, the electron supply layer 18 is removed from the element separation region R2. The element region R1 is in conformance with the planar shape of the electron supply layer 18 and is, for example, rectangular in plan view.

The electron transit layer 16 may include a peripheral part 16P exposed around the electron supply layer 18 in plan view. The peripheral part 16P of the electron transit layer 16 defines the area of the element separation region R2. The element separation region R2 is in conformance with the planar shape of the peripheral part 16P of the electron transit layer 16 and is, for example, annular in plan view.

In the example shown in FIGS. 1 and 2, the electron transit layer 16 includes an outer peripheral side surface 16SA located on an outer border of the element separation region R2 and may include an inner peripheral side surface 16SB located on an inner border of the element separation region R2. The inner peripheral side surface 16SB of the electron transit layer 16 is continuous with the peripheral side surface 18SA of the electron supply layer 18 and is located on the boundary B1 of the element region R1 and the element separation region R2. In this structure, together with the electron supply layer 18, a portion of the electron transit layer 16 (surface of the peripheral part 16P of the electron transit layer 16) is removed from the element separation region R2. Thus, the element separation region R2 includes the electron transit layer 16 (as well as the buffer layer 14 and the substrate 12).

In the example shown in FIG. 2, since the electron transit layer 16 includes the inner peripheral side surface 16SB, the electron transit layer 16 (the peripheral part 16P) of the element separation region R2 is formed in a stepped manner from the electron transit layer 16 of the element region R1. However, the electron transit layer 16 does not necessarily have to include the inner peripheral side surface 16SB. The inner peripheral side surface 16SB is formed during etching (e.g., mesa-etching) of the electron supply layer 18 in the element separation region R2, which removes the surface of the peripheral part 16P, which is located in a lower layer. However, without the removal of the surface of the peripheral part 16P, only the electron supply layer 18 may be removed from the element separation region R2. When etching is performed so that the surface of the peripheral part 16P of the electron transit layer 16 is removed, the electron supply layer 18 may be completely removed from the element separation region R2.

In the example shown in FIG. 2, the element separation region R2 is formed by etching. Alternatively, the element separation region may be formed by ion implantation that eliminates a 2DEG 20. In this case, the electron supply layer 18 remains but no longer plays the role of supplying electrons. Thus, the boundary where the ion implantation was performed on the electron supply layer 18 defines the area of the element region R1.

The electron transit layer 16 is cut at the element separation region R2. In the example shown in FIG. 2, together with the electron transit layer 16, the buffer layer 14 and the substrate 12 are cut at the element separation region R2. The outer peripheral side surface 16SA of the electron transit layer 16 and the outer peripheral side surfaces of the buffer layer 14 and the substrate 12 that are cut at the position of the outer peripheral side surface 16SA correspond to a cut surface of the semiconductor device 10. In other words, the position of the outer peripheral side surface 16SA corresponds to the position of a scribe line SL, or cutting position, used in singulation of multiple semiconductor devices 10 formed on a single large substrate (the substrate 12).

As shown in FIGS. 1 and 2, the semiconductor device 10 includes one or more (four in the example shown in FIG. 1) source electrodes 22A, 22B, 22C, 22D arranged on the electron supply layer 18. The source electrodes 22A, 22B, 22C, and 22D are in ohmic contact with, that is, electrically connected to, the 2DEG 20 present immediately below the electron supply layer 18. In the description hereafter, the source electrodes 22A, 22B, 22C, and 22D are collectively referred to as the source electrodes 22 unless otherwise distinguished.

As shown in FIG. 1, each of the source electrodes 22 is, for example, rectangular in plan view. In an example, each of the source electrodes 22 has the form of a strip having an electrode width in a first direction (X-direction in FIG. 1) in plan view and an electrode length in a second direction (Y-direction in FIG. 1) that is orthogonal to the first direction in plan view. The electrode length is greater than the electrode width. The source electrodes 22A, 22B, 22C, and 22D are spaced apart from each other in the first direction (X-direction). In the description hereafter, the X-direction may be referred to as the first direction, and the Y-direction may be referred to as the second direction.

Each of the source electrodes 22 may be formed of a single metal layer or a combination of metal layers (e.g., titanium (Ti) layer, titanium nitride (TiN) layer, Al layer, aluminum silicon copper (AlSiCu) layer, and aluminum copper (AlCu) layer). In the example shown in FIGS. 1 and 2, each of the source electrodes 22 is formed of the combination of a Ti layer and an Al layer.

The semiconductor device 10 further includes one or more (three in the example shown in FIG. 1) drain electrodes 24A, 24B, and 24C arranged on the electron supply layer 18. The drain electrodes 24A, 24B, and 24C are in ohmic contact with, that is, electrically connected to, the 2DEG 20 present immediately below the electron supply layer 18. In the description hereafter, the drain electrodes 24A, 24B, and 24C are collectively referred to as the drain electrodes 24 unless otherwise distinguished.

As shown in FIG. 1, each of the drain electrodes 24 is, for example, rectangular in plan view. In an example, each of the drain electrodes 24 has the form of a strip having an electrode width in the first direction (X-direction) and an electrode length in the second direction (Y-direction). The electrode length is greater than the electrode width. The length of the drain electrodes 24 is smaller than the length of the source electrodes 22.

The drain electrodes 24A, 24B, and 24C are spaced apart from each other in the first direction (X-direction). In the example shown in FIG. 1, the drain electrode 24A is arranged between the source electrodes 22A and 22B, located adjacent to the drain electrode 24A, and spaced apart from the source electrodes 22A and 22B. The drain electrode 24B is arranged between the source electrodes 22B and 22C, located adjacent to the drain electrode 24B, and spaced apart from the source electrodes 22B and 22C. The drain electrode 24C is arranged between the source electrodes 22C and 22D, located adjacent to the drain electrode 24C, and spaced apart from the source electrodes 22C and 22D.

In the same manner as the source electrodes 22, each of the drain electrodes 24 may be formed of a single metal layer or a combination of metal layers (e.g., Ti layer, TiN layer, Al layer, AlSiCu layer, and AlCu layer). In the example shown in FIGS. 1 and 2, each of the drain electrodes 24 is formed of the combination of a Ti layer and an Al layer.

The semiconductor device 10 further includes one or more (three in the example shown in FIG. 1) gate portions 26A, 26B, and 26C arranged on the electron supply layer 18 and including an acceptor impurity. In the description hereafter, the gate portions 26A, 26B, and 26C are collectively referred to as the gate portions 26 unless otherwise distinguished. The gate portions 26 are each an example of a third semiconductor layer.

As shown in FIG. 1, each of the gate portions 26 is, for example, rectangular in plan view. The gate portion 26 does not necessarily have to have a closed annular shape (a continuous shape with no ends or a shape of a complete loop). The gate portion 26 may be, for example, open-annular-shaped and have a slit (gap) such as a C-shape in plan view.

In the example shown in FIG. 1, each of the gate portions 26 includes a first gate body 261 and a second gate body 262 extending parallel to each other in the second direction (Y-direction) and a first connector 263 and a second connector 264 extending parallel to each other in the first direction (X-direction). The first gate body 261 and the second gate body 262 are connected to each other by the first connector 263 and the second connector 264 to form the annular gate portion 26. In this structure, for example, the first connector 263 (or the second connector 264) is entirely or partially omitted so that the gate portion 26 is C-shaped in plan view.

Each of the first gate body 261 and the second gate body 262 has a gate width W1 in the first direction (X-direction). Each of the first connector 263 and the second connector 264 has a width W2 in the second direction (Y-direction). In the example shown in FIG. 1, the gate width W1 is slightly smaller than the width W2 but may be equal to the width W2.

The gate portions 26A, 26B, and 26C are spaced apart from each other in the first direction (X-direction). In the example shown in FIG. 1, the gate portion 26A is arranged between the source electrodes 22A and 22B, located adjacent to the gate portion 26A, and surrounds the drain electrode 24A in plan view. Thus, the first gate body 261 of the gate portion 26A is located between the source electrode 22A and the drain electrode 24A. Also, the second gate body 262 of the gate portion 26A is located between the source electrode 22B and the drain electrode 24A.

In the same manner, the gate portion 26B is arranged between the source electrodes 22B and 22C, located adjacent to the gate portion 26B, and surrounds the drain electrode 24B in plan view. Thus, the first gate body 261 of the gate portion 26B is located between the source electrode 22B and the drain electrode 24B. Also, the second gate body 262 of the gate portion 26B is located between the source electrode 22C and the drain electrode 24B.

In the same manner, the gate portion 26C is arranged between the source electrodes 22C and 22D, located adjacent to the gate portion 26C, and surrounds the drain electrode 24C in plan view. Thus, the first gate body 261 of the gate portion 26C is located between the source electrode 22C and the drain electrode 24C. Also, the second gate body 262 of the gate portion 26C is located between the source electrode 22D and the drain electrode 24C.

The gate portions 26 may be formed of a nitride semiconductor having a band gap that is smaller than that of the electron supply layer 18. In an example, when the electron supply layer 18 is an AlGaN layer, the gate portion 26 may be a GaN layer (p-type GaN layer) doped with an acceptor impurity. In an example, the gate portions 26 may include at least one of zinc (Zn), magnesium (Mg), and carbon (C) as an acceptor impurity. The maximum concentration of the acceptor impurity in the gate portions 26 is, for example, greater than or equal to 7×10¹⁸ cm⁻³ and 1×10²⁰ cm⁻³.

The thickness of the gate portion 26 is not particularly limited and may be determined taking into consideration gate breakdown voltage. The thickness of the gate portion 26 may be, for example, greater than or equal to 80 nm and less than or equal to 150 nm. The cross-sectional shape of the gate portion 26 along the ZX-plane shown in FIG. 2 is not particularly limited and may be, for example, rectangular, trapezoidal, ridged, or any other shape. The gate width W1 of the first and second gate bodies 261 and 262 is not particularly limited and may be, for example, greater than or equal to 0.4 μm and less than or equal to 1.0 μm.

The semiconductor device 10 further includes one or more (three in the example shown in FIG. 1) gate electrodes 28A, 28B, and 28C formed on the gate portions 26 (the gate portions 26A, 26B, and 26C in the example shown in FIG. 1). In the description hereafter, the gate electrodes 28A, 28B, and 28C are collectively referred to as the gate electrodes 28 unless otherwise distinguished.

As shown in FIG. 1, each of the gate electrodes 28 is, for example, annular in plan view. However, in the same manner as the gate portion 26, the gate electrode 28 does not necessarily have to have a closed annular shape and may be, for example, C-shaped in plan view in conformance with the planar shape of the gate portion 26 located in a lower layer

In the example shown in FIG. 1, each of the gate electrodes 28 includes a first gate electrode portion 281 and a second gate electrode portion 282 extending parallel to each other in the second direction (Y-direction) and a first connector 283 and a second connector 284 extending parallel to each other in the first direction (X-direction). The first gate electrode portion 281 and the second gate electrode portion 282 are connected to each other by the first connector 283 and the second connector 284 to form the annular gate electrode 28.

The first gate electrode portion 281 and the second gate electrode portion 282 each have an electrode width (not shown) that is slightly smaller than the gate width W1 of the gate portion 26 (the first gate body 261 and the second gate body 262) in the first direction (X-direction). The first connector 283 and the second connector 284 each have an electrode width (not shown) that is slightly smaller than the width W2 of the gate portion 26 (the first connector 263 and the second connector 264) in the second direction (Y-direction).

The gate electrode 28 may be formed of one or more metal layers. In an example, the gate electrode 28 may be a TiN layer. Alternatively, the gate electrode 28 may be formed of a first metal layer using Ti and a second metal layer formed on the first metal layer and using TiN. The thickness of the gate electrodes 28 is not particularly limited and may be, for example, greater than or equal to 50 nm and less than or equal to 200 nm. The gate electrode 28 that uses a TiN layer forms a Schottky junction with the gate portion 26 located in a lower layer.

In the example shown in FIGS. 1 and 2, the gate electrode 28A is arranged on the gate portion 26A. Thus, the source electrode 22A, the first gate electrode portion 281 of the gate electrode 28A, the drain electrode 24A, the second gate electrode portion 282 of the gate electrode 28A, and the source electrode 22B are separated and adjacent to each other in the first direction (X-direction) in plan view.

In the same manner, the gate electrode 28B is arranged on the gate portion 26B. Thus, the source electrode 22B, the first gate electrode portion 281 of the gate electrode 28B, the drain electrode 24B, the second gate electrode portion 282 of the gate electrode 28B, and the source electrode 22C are separated and adjacent to each other in the first direction (X-direction) in plan view.

In the same manner, the gate electrode 28C is arranged on the gate portion 26C. Thus, the source electrode 22C, the first gate electrode portion 281 of the gate electrode 28C, the drain electrode 24C, the second gate electrode portion 282 of the gate electrode 28C, and the source electrode 22D are separated and adjacent to each other in the first direction (X-direction) in plan view.

As described above, the source electrode 22, the gate electrode 28, and the drain electrode 24 are repeatedly arranged in the first direction so that the source electrode 22, the gate electrode 28, and the drain electrode 24 are separated and adjacent to each other in the first direction (X-direction) in plan view and the gate electrode 28 is located between the source electrode 22 and the drain electrode 24.

In the example shown in FIG. 1, in the first direction (from the left toward the right), the source electrode 22D, the gate electrode 28C (the second gate electrode portion 282), the drain electrode 24C, the gate electrode 28C (the first gate electrode portion 281), the source electrode 22C, the gate electrode 28B (the second gate electrode portion 282), the drain electrode 24B, the gate electrode 28B (the first gate electrode portion 281), the source electrode 22B, the gate electrode 28A (the second gate electrode portion 282), the drain electrode 24A, the gate electrode 28A (the first gate electrode portion 281), and the source electrode 22A are arranged. This arrangement forms six FETs (HEMTs) in the element region R1 of the semiconductor device 10. Each of the HEMTs is formed of the electron transit layer 16, the electron supply layer 18, the gate portion 26, the gate electrode 28, the source electrode 22, and the drain electrode 24.

In the semiconductor device 10, the gate portion 26 (e.g., p-type GaN layer) is arranged under the gate electrode 28. This increases the energy levels of the electron transit layer 16 and the electron supply layer 18 in a region immediately below the gate portion 26. Therefore, when the material and the thickness of the electron supply layer 18 are appropriately set, the source-drain conductive path (channel) formed of the 2DEG 20 disappears from the region immediately below the gate portion 26 in a zero bias state, in which no voltage is applied to the gate electrode 28 relative to the source electrode 22. Thus, the conductive path (channel) is disconnected. This obtains a normally-off-type HEMT in which the threshold voltage has a positive value.

As shown in FIG. 1, the semiconductor device 10 further includes a guard ring 30 arranged on the electron supply layer 18 in a peripheral part R11 of the element region R1. The guard ring 30 may have a closed annular shape in plan view.

In the present disclosure, the peripheral part R11 of the element region R1 refers to a part of the element region R1 located outside the active region of the element region R1 in plan view. In the example shown in FIGS. 1 and 2, the active region corresponds to a part of the element region R1 in which the source electrodes 22, the drain electrodes 24, the gate portions 26, and the gate electrodes 28 are arranged. In an example, the peripheral part R11 of the element region R1 is a part of the element region R1 in the vicinity of the boundary B1 of the element region R1 and the element separation region R2.

As shown in FIGS. 1 and 2, the guard ring 30 includes a shield portion 32 arranged on the electron supply layer 18 and including an acceptor impurity and a first shield electrode 34 arranged on the shield portion 32. The shield portion 32 is an example of a fourth semiconductor layer. The first shield electrode 34 is an example of a first electrode.

As shown in FIG. 1, the shield portion 32 is, for example, annular in plan view. In the example shown in FIG. 1, the shield portion 32 includes a first shield part 321 and a second shield part 322 extending parallel to each other in the second direction (Y-direction) and a third shield part 323 and a fourth shield part 324 extending parallel to each other in the first direction (X-direction). The first shield part 321 and the second shield part 322 are connected to each other by the third shield part 323 and the fourth shield part 324 to form the annular shield portion 32.

Each of the first shield part 321 and the second shield part 322 has a shield width W3 in the first direction (X-direction). Each of the third shield part 323 and the fourth shield part 324 has a shield width W4 in the second direction (Y-direction). In the example shown in FIG. 1, the shield width W3 is slightly greater than the shield width W4. However, the shield width W3 may be equal to the shield width W4.

The shield portion 32 may be formed of a nitride semiconductor having a band gap that is smaller than that of the electron supply layer 18. In an example, when the electron supply layer 18 is an AlGaN layer, the shield portion 32 may be a GaN layer (p-type GaN layer) doped with an acceptor impurity. In an example, the shield portion 32 may include at least one of Zn, Mg, and C as the acceptor impurity. The maximum concentration of the acceptor impurity in the shield portion 32 is, for example, greater than or equal to 7×10¹⁸ cm⁻³ and less than or equal to 1×10²⁰ cm⁻³. In an example, the shield portion 32 and the gate portions 26 may have the same structure and may be formed in the same manufacturing step.

The thickness of the shield portion 32 is not particularly limited and may be, for example, greater than or equal to 80 nm and less than or equal to 150 nm. The cross-sectional shape of the shield portion 32 along the ZX-plane shown in FIG. 2 is not particularly limited and may be, for example, rectangular, trapezoidal, ridged, or any other shape. In an example, the shield portion 32 and the gate portions 26 may have the same thickness and the same cross-sectional shape. The shield widths W3 and W4 of the shield portion 32 are not particularly limited and may be determined taking into consideration the shield effect of the shield portion 32. In an example, the shield width W3 of the first and second shield parts 321 and 322 of the shield portion 32 may be set to a greater value than the gate width W1 of the first and second gate bodies 261 and 262 of the gate portion 26.

The first shield electrode 34 is, for example, annular in plan view in the same manner as the shield portion 32. In the example shown in FIG. 1, the first shield electrode 34 includes a first electrode part 341 and a second electrode part 342 extending parallel to each other in the second direction (Y-direction) and a third electrode part 343 and a fourth electrode part 344 extending parallel to each other in the first direction (X-direction). The first electrode part 341 and the second electrode part 342 are connected to each other by the third electrode part 343 and the fourth electrode part 344 to form the annular first shield electrode 34.

Each of the first electrode part 341 and the second electrode part 342 has an electrode width (not shown) that is slightly smaller than the shield width W3 of the shield portion 32 (the first shield part 321 and the second shield part 322) in the first direction (X-direction). Each of the third electrode part 343 and the fourth electrode part 344 has a width (not shown) that is slightly smaller than the shield width W4 of the shield portion 32 (the third shield part 323 and the fourth shield part 324) in the second direction (Y-direction).

The first shield electrode 34 may be formed of one or more metal layers. The first shield electrode 34 may be, for example, a TiN layer. Alternatively, the first shield electrode 34 may be formed of a combination of a Ti layer and an Al layer. Alternatively, the first shield electrode 34 may be formed of a combination of a Ti layer, a TiN layer, an Al layer, an AlSiCu layer, an AlCu layer, and the like. In the first embodiment, the first shield electrode 34 is a TiN layer.

The thickness of the first shield electrode 34 is not particularly limited and may be, for example, greater than or equal to 50 nm and less than or equal to 200 nm. In an example, the first shield electrode 34 and the gate electrodes 28 may be formed in the same manufacturing step using a TiN layer. The first shield electrode 34 that uses a TiN layer forms a Schottky junction with the shield portion 32 located in a lower layer.

As shown in FIG. 1, the guard ring 30 annularly surrounds the source electrodes 22, the gate electrodes 28, and the drain electrodes 24 that are repeatedly arranged in the first direction (X-direction) in plan view. In addition, the guard ring 30 is located adjacent to the source electrode 22 in the first direction.

In the example shown in FIG. 1, the first shield part 321 and the first electrode part 341, which form a portion (right portion in FIG. 1) of the guard ring 30, are located adjacent to the source electrode 22A in the first direction. Thus, the 2DEG 20 extending in the electron transit layer 16 between the source electrode 22A and the guard ring 30 located adjacent to the source electrode 22A has a source potential.

The second shield part 322 and the second electrode part 342, which form another portion (left portion in FIG. 1) of the guard ring 30, is located adjacent to the source electrode 22D in the first direction. Thus, the 2DEG 20 extending in the electron transit layer 16 between the source electrode 22D and the guard ring 30 located adjacent to the source electrode 22D has a source potential.

An example of the wiring structure of the semiconductor device 10 shown in FIG. 1 will now be described.

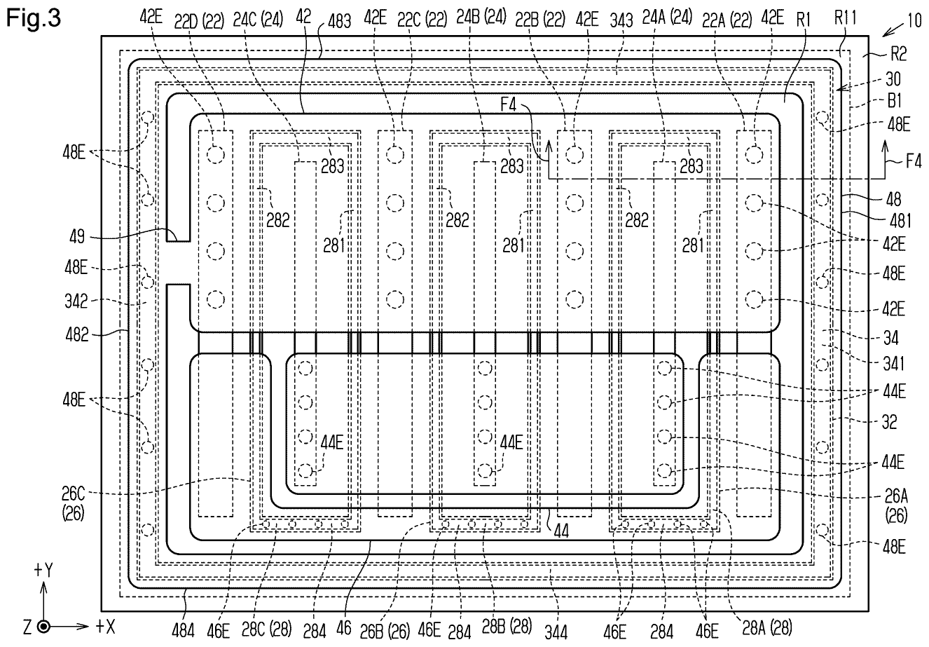

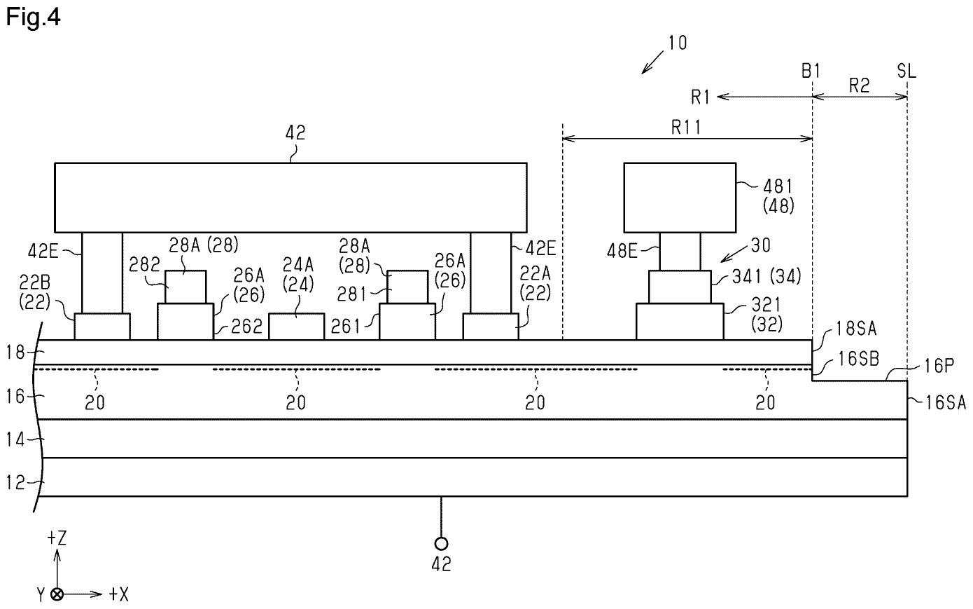

FIG. 3 is a schematic plan view of the semiconductor device 10 shown in FIG. 1 having an exemplary wiring structure. FIG. 4 is a schematic cross-sectional view taken along line F4-F4 in FIG. 3.

As shown in FIG. 3, the semiconductor device 10 includes a source pad 42 connected to the source electrodes 22A, 22B, 22C, and 22D, a drain pad 44 connected to the drain electrodes 24A, 24B, and 24C, and a gate pad 46 connected to the gate electrodes 28A, 28B, and 28C. A source voltage, a drain voltage, and a gate voltage are applied to the source pad 42, the drain pad 44, and the gate pad 46, respectively. The source voltage may be a ground voltage. The source pad 42, the drain pad 44, and the gate pad 46 may be formed of, for example, a metal layer using Au, Cu, or Al.

As shown in FIGS. 3 and 4, the source pad 42 is connected to the source electrodes 22A, 22B, 22C, and 22D by source connection electrodes 42E. In the same manner, although not shown in the cross-sectional view, the drain pad 44 is connected to the drain electrodes 24A, 24B, and 24C by drain connection electrodes 44E. The gate pad 46 is also connected to the gate electrodes 28A, 28B, and 28C by gate connection electrodes 46E.

The source connection electrodes 42E, the drain connection electrodes 44E, and the gate connection electrodes 46E may be formed from, for example, a metal material such as Au, Cu, or Al. In an example, the source connection electrodes 42E, the drain connection electrodes 44E, and the gate connection electrodes 46E may be formed integrally with the source pad 42, the drain pad 44, and the gate pad 46, respectively. Alternatively, the source connection electrodes 42E and the drain connection electrodes 44E may be formed from a material that differs from that of the source pad 42 and the drain pad 44, respectively. In an example, the source connection electrodes 42E and the drain connection electrodes 44E may be a plug electrode that uses tungsten (W).

In the example shown in FIG. 3, the gate connection electrodes 46E are arranged on the second connectors 284 of the gate electrodes 28A, 28B, and 28C. Thus, the first and second gate electrode portions 281 and 282 of each gate electrode 28 are connected to the gate pad 46 by the second connectors 284 and the gate connection electrodes 46E. In this case, in the gate electrode 28, when the electrode width of the second connector 284 is greater than the electrode width of the first and second gate electrode portions 281 and 282, the area of contact of the second connector 284 with the gate connection electrode 46E is increased. This increases connection reliability.

The source pad 42, the drain pad 44, and the gate pad 46 are flat. In the example shown in FIG. 3, the source pad 42 and the drain pad 44 are each rectangular. The gate pad 46 is U-shaped. In this example, the source pad 42 occupies the area of approximately one-half of the active region in the element region R1. The drain pad 44 and the gate pad 46 together occupy the area of the remaining approximately one-half of the active region. Thus, in plan view, the source pad 42, the drain pad 44, and the gate pad 46 substantially entirely cover the active region of the element region R1.

In other words, the source pad 42, the drain pad 44, and the gate pad 46 are entirely arranged in the active region of the element region R1. The structure in which the source pad 42, the drain pad 44, and the gate pad 46 are arranged in the active region may be referred to as a pad over active (POA) structure. Use of the POA structure reduces the area of a non-active region (i.e., peripheral part R11) occupying the element region R1. This reduces the total area of the element region R1, and ultimately, the chip area (the total area of the element region R1 and the element separation region R2).

As shown in FIGS. 3 and 4, the semiconductor device 10 further includes a wiring electrode 48 connected to the first shield electrode 34 of the guard ring 30. The wiring electrode 48 is, for example, annular in plan view. However, the shape of the wiring electrode 48 is not particularly limited. For example, the wiring electrode 48 does not necessarily have a closed annular shape and may have an open annular shape.

In the example shown in FIG. 3, the wiring electrode 48 includes a first electrode part 481 and a second electrode part 482 extending parallel to each other in the second direction (Y-direction) and a third electrode part 483 and a fourth electrode part 484 extending parallel to each other in the first direction (X-direction). The first electrode part 481 and the second electrode part 482 are connected to each other by the third electrode part 483 and the fourth electrode part 484 to form the annular wiring electrode 48.

The wiring electrode 48 is connected to the source pad 42 by a joint 49. In the example shown in FIG. 3, the joint 49 is arranged in a position so that the joint 49 connects the source pad 42 and the second electrode part 482 of the wiring electrode 48. However, the arrangement of the joint 49 is not limited to a particular position.

The wiring electrode 48 is connected to the first shield electrode 34 by guard ring connection electrodes 48E. The first shield electrode 34 of the guard ring 30 is electrically connected to the source pad 42 by the guard ring connection electrodes 48E, the wiring electrode 48, and the joint 49. Thus, the first shield electrode 34 is set to the same potential as the source voltage applied from the source pad 42 to the source electrode 22. In other words, the first shield electrode 34 is electrically connected to the source electrode 22. Although the wiring structure is not shown in detail, the substrate 12 is also electrically connected to the source pad 42 (refer to FIG. 4). Thus, the substrate 12 is also set to the source potential.

In the example shown in FIGS. 3 and 4, the guard ring connection electrodes 48E are arranged on the first and second electrode parts 341 and 342 of the first shield electrode 34. More specifically, the guard ring connection electrodes 48E are arranged in a position where the first electrode part 341 of the first shield electrode 34 is connected to the first electrode part 481 of the wiring electrode 48 and a position where the second electrode part 342 of the first shield electrode 34 is connected to the second electrode part 482 of the wiring electrode 48. However, the arrangement of the guard ring connection electrodes 48E is not limited to a particular position.

The wiring electrode 48, the guard ring connection electrodes 48E, and the joint 49 may be formed from, for example, a metal material such as Au, Cu, or Al. In an example, the wiring electrode 48, the guard ring connection electrodes 48E, and the joint 49 may be formed integrally.

Although not shown in detail, the semiconductor device 10 includes an insulation layer such as a passivation layer formed on the electron supply layer 18. The insulation layer covers the electron supply layer 18, the source electrode 22, the drain electrode 24, the gate portions 26, the gate electrodes 28, the guard ring 30 (the shield portion 32 and the first shield electrode 34), the source connection electrodes 42E, the drain connection electrodes 44E, the gate connection electrodes 46E, and the guard ring connection electrodes 48E. In addition, the insulation layer may cover side surfaces of the source pad 42, the drain pad 44, the gate pad 46, the wiring electrode 48, and the joint 49. The insulation layer includes vias in which the source connection electrodes 42E, the drain connection electrodes 44E, the gate connection electrodes 46E, and the guard ring connection electrodes 48E are embedded.

The operation of the semiconductor device 10 of the first embodiment will now be described.

As shown in FIG. 2, the gate portions 26 (e.g., p-type GaN layer) are arranged under the gate electrodes 28 in the element region R1 in which the HEMT is formed. Therefore, when the material and the thickness of the electron supply layer 18 are appropriately set, the channel formed of the 2DEG 20 disappears from the region immediately below the gate portions 26 in the zero bias state, in which no gate voltage is applied to the gate electrodes 28. Thus, the normally-off operation is performed. When a gate voltage exceeding a threshold voltage is applied to the gate electrodes 28, the channel is formed of the 2DEG 20 in the region immediately below the gate portions 26 and connects the source and the drain. This shifts the HEMT to the on state.

The guard ring 30 is arranged in the peripheral part R11 of the element region R1. The guard ring 30 includes the shield portion 32 (e.g., p-type GaN layer) arranged on the electron supply layer 18 and the first shield electrode 34 arranged on the shield portion 32. The first shield electrode 34 is electrically connected to the source pad 42. The first shield electrode 34 receives a source voltage (ground voltage) applied from the source pad 42 to the source electrode 22.

As shown in FIG. 1, the guard ring 30 is located adjacent to the source electrodes 22A and 22D in the first direction (X-direction). Thus, the 2DEG 20 extending in the electron transit layer 16 between the source electrode 22A and the guard ring 30 located adjacent to the source electrode 22A has a source potential. In the same manner, the 2DEG 20 extending in the electron transit layer 16 between the source electrode 22D and the guard ring 30 located adjacent to the source electrode 22D has a source potential. The 2DEG 20 extending in the region outside the guard ring 30 (region between the guard ring 30 and the boundary B1) has a floating potential.

Thus, the first shield electrode 34 of the guard ring 30 has substantially the same potential as the 2DEG 20 extending from the region immediately below the source electrodes 22A and 22D, which are located adjacent to the guard ring 30, to the position immediately below an inner edge of the guard ring 30. The expression “substantially the same potential” means that when current flows between the source and the drain of the HEMT through the channel (the 2DEG 20), the potential of the 2DEG 20 extending between the guard ring 30 and the source electrode 22A and between the guard ring 30 and the source electrode 22D may become slightly higher than the potential of the first shield electrode 34 due to a resistance component. When no current flows to the HEMT, the potential of the 2DEG 20 between the guard ring 30 and each of the source electrodes 22A and 22D is the same as the potential of the first shield electrode 34.

As described above, the first shield electrode 34 has substantially the same potential (in this case, source potential) as the 2DEG 20 present between the guard ring 30 and each of the source electrodes 22A and 22D. Thus, the 2DEG 20 in the region immediately below the guard ring 30 (the shield portion 32) is depleted (is no longer present) and maintains the depletion state.

Thus, the disconnection region of the 2DEG 20 is annularly formed immediately below the guard ring 30 arranged in the peripheral part R11 of the element region R1. As a result, the 2DEG 20 that is present in the active region of the element region R1 is electrically disconnected from the outside of the semiconductor device 10 by the disconnection region of the 2DEG 20 in the peripheral part R11 of the element region R1. This hampers entrance of surge into the active region from the outside of the semiconductor device 10 through the 2DEG 20.

In an example, during dicing that uses a dicing blade, surge may enter the peripheral part R11 of the element region R1 from the scribe line SL through the element separation region R2. In this case, entrance of surge into the 2DEG 20 in the active region may be hampered by the disconnection region of the 2DEG 20 located immediately below the guard ring 30. This surge shield effect is obtained along the entire perimeter of the peripheral part R11 of the element region R1. In addition to the disconnection region of the 2DEG 20 immediately below the guard ring 30, the first shield electrode 34 of the guard ring also shields against surge from the outside.

As shown in FIG. 2, when the 2DEG 20 extending in a region outside the guard ring 30 is exposed from the inner peripheral side surface 16SB of the electron transit layer 16, surge is more likely to enter the peripheral part R11 of the element region R1 from the exposed 2DEG 20 as compared to other locations. Even in this case, entrance of surge into the active region is hampered by the disconnection region of the 2DEG 20 present immediately below the guard ring 30.

As shown in FIG. 3, the semiconductor device 10 has the POA structure. In the POA structure, the source pad 42, the drain pad 44, and the gate pad 46 are arranged in the active region. This reduces the area of the non-active region (i.e., the peripheral part R11) occupying the element region R1, thereby reducing the chip area. Since the POA structure shortens the distance between the scribe line SL (or, the boundary B1 of the element region R1 and the element separation region R2) and the active region, it is desirable that the guard ring structure of the semiconductor device 10 have even higher surge resistance.

In this regard, as described above, the guard ring 30 annularly forms the disconnection region of the 2DEG 20 in the peripheral part R11 of the element region R1 to electrically disconnect the 2DEG 20 of the active region from the outside. This allows the guard ring 30 to be formed in a position proximate to the active region and have a smaller width. Thus, improvement in surge resistance and reduction in the chip area are achieved.

The semiconductor device 10 of the first embodiment has the following advantages.

(1-1) The semiconductor device 10 includes the guard ring 30 arranged on the electron supply layer 18 in the peripheral part R11 of the element region R1. The guard ring 30 includes the shield portion 32 (e.g., p-type GaN layer) arranged on the electron supply layer 18 and including an acceptor impurity and the first shield electrode 34 arranged on the shield portion 32 and electrically connected to the source electrode 22. The first shield electrode 34 is set to substantially the same potential as the potential (source potential) of the 2DEG 20 present adjacent to the inner edge of the guard ring 30 in plan view. The 2DEG 20 in the region immediately below the shield portion 32 is depleted (is no longer present) and maintains the depletion state. Thus, the disconnection region of the 2DEG 20 is annularly formed immediately below the guard ring 30 arranged in the peripheral part R11 of the element region R1. As a result, the 2DEG 20 present in the active region of the element region R1 is electrically disconnected from the outside of the semiconductor device 10 by the disconnection region of the 2DEG 20 in the peripheral part R11 of the element region R1. This hampers entrance of surge into the active region from the outside of the semiconductor device 10 through the 2DEG 20. The guard ring 30 improves surge resistance.

(1-2) The element separation region R2 includes the substrate 12 and the electron transit layer 16. The electron supply layer 18 is removed from the element separation region R2. Since the element separation region R2 does not include the electron supply layer 18, the 2DEG 20 is not generated in the electron transit layer 16 in the element separation region R2 (thus, the element separation region R2 may be referred to as a high resistance region as compared to the element region R1). In this structure, surge may enter the peripheral part R11 of the element region R1 from, for example, the surface of the electron transit layer 16 of the element separation region R2. For example, as shown in FIG. 2, when the surface of the electron transit layer 16 is removed from the element separation region R2 together with the electron supply layer 18, the 2DEG 20 is exposed on the inner peripheral side surface 16SB of the electron transit layer 16 located on the boundary B1 of the element region R1 and the element separation region R2. Surge is likely to enter the exposed 2DEG 20. Even in this structure, the guard ring 30 arranged in the peripheral part R11 hampers entrance of surge, thereby improving surge resistance.

(1-3) The electron transit layer 16 and the substrate 12 are cut at the element separation region R2. In other words, the scribe line SL is set in the element separation region R2. Hence, dicing is performed on the element separation region R2, which does not include the 2DEG 20. Thus, when surge occurs during dicing, the surge is less likely to enter the 2DEG 20 in the element region R1.

(1-4) The electron transit layer 16 is a GaN layer. The electron supply layer 18 is an AlGaN layer. In this structure, the 2DEG 20 is formed in the GaN layer (electron transit layer 16) in the vicinity of the interface of the GaN layer (electron transit layer 16) and the AlGaN layer (electron supply layer 18), which form a heterojunction with each other. When the guard ring 30 is used in this structure, the semiconductor device 10 (HEMT) has an improved surge resistance while hampering entrance of surge into the 2DEG 20 of the element region R1.

(1-5) The drain electrode 24 is surrounded by the gate portion 26 in plan view (for example, refer to FIG. 1). This structure hampers leakage of a high voltage applied to the drain electrode 24 to a region outside the gate portion 26 (i.e., to source electrode 22). Thus, the reliability of the semiconductor device 10 (HEMT) is increased. In addition, variations in the potential of the 2DEG 20 present immediately below the source electrode 22 are limited. This allows the potential of the 2DEG 20 to be appropriately maintained at the source potential that is equal to the ground potential. As a result, operation of the HEMT and operation of the guard ring 30 are appropriately maintained.

(1-6) The source electrode 22, the gate electrode 28, and the drain electrode 24 are repeatedly arranged in the first direction so that the source electrode 22, the gate electrode 28, and the drain electrode 24 are separated and adjacent to each other in the first direction (X-direction) in plan view and the gate electrode 28 is located between the source electrode 22 and the drain electrode 24. With this structure, multiple (six in the example shown in FIG. 1) HEMTs are arranged in the element region R1 (active region) at a high density.

(1-7) The guard ring 30 is located adjacent to the source electrodes 22A and 22D in the first direction (X-direction). The 2DEG 20 of the electron transit layer 16 extending between the guard ring 30 and the source electrode 22A and between the guard ring 30 and the source electrode 22D has a source potential. With this structure, when the source voltage is applied to the guard ring 30 (the first shield electrode 34), the 2DEG 20 present immediately below the guard ring 30 (the shield portion 32) is depleted to form the electrically disconnection region of the 2DEG 20.

(1-8) The shield width W3 of the shield portion 32 (the first and second shield parts 321 and 322) of the guard ring 30 is set to a greater value than the gate width W1 of the gate portion 26 (the first and second gate bodies 261 and 262). With this structure, the depletion region of the 2DEG 20 present immediately below the shield portion 32 (the first and second shield parts 321 and 322) is larger than the depletion region of the 2DEG 20 present immediately below the gate portion 26 (the first and second gate bodies 261 and 262). This further improves surge resistance. In particular, since the source electrode 22, the gate electrode 28, and the drain electrode 24 are located adjacent to each other in the first direction (X-direction), when the width (i.e., the shield width W3) of the shield portion 32 in the first direction is larger than the width (i.e., the gate width W1) of the gate portion 26 in the first direction, surge resistance is improved effectively.

(1-9) The substrate 12 is electrically conductive and is set to be equal in potential to the source electrode 22. In other words, the potential of the substrate 12 is the same as the source potential of the 2DEG 20. This limits leakage current flowing to the substrate 12 from the element separation region R2 through the surface of the semiconductor device 10 located on the scribe line SL.

(1-10) The FET (HEMT) formed in the element region R1 is of a normally-off type. In this case, the shield portion 32 of the guard ring 30 may be formed in the same manufacturing step as the gate portion 26.

(1-11) The first shield electrode 34 of the guard ring 30 and the gate electrodes 28 are formed from the same material (e.g., TiN layer). In this case, the first shield electrode 34 of the guard ring 30 may be formed in the same manufacturing step as the gate electrodes 28.

(1-12) The source pad 42, the drain pad 44, and the gate pad 46 are arranged in the active region of the element region R1. In other words, the semiconductor device 10 has the POA structure. Use of the POA structure reduces the area of a non-active region (i.e., peripheral part R11) occupying the element region R1. This reduces the total area of the element region R1, and ultimately, the chip area (the total area of the element region R1 and the element separation region R2). Since the POA structure shortens the distance between the scribe line SL (or, the boundary B1 of the element region R1 and the element separation region R2) and the active region, it is desirable that the guard ring structure of the semiconductor device 10 have even higher surge resistance. In this regard, the guard ring 30 annularly forms the disconnection region of the 2DEG 20 in the peripheral part R11 of the element region R1 to electrically disconnect the 2DEG 20 of the active region from the outside. This allows the guard ring 30 to be formed in a position proximate to the active region and have a smaller width. Thus, improvement in surge resistance and reduction in the chip area are achieved.

(1-13) The source connection electrodes 42E, which connect the source pad 42 and the source electrodes 22, may be formed from the same material (e.g., Au, Cu, or Al) as that of the source pad 42. In the same manner, the drain connection electrodes 44E, which connect the drain pad 44 and the drain electrodes 24, may be formed from the same material as that of the drain pad 44. The gate connection electrodes 46E, which connect the gate pad 46 and the gate electrodes 28, may be formed from the same material as that of the gate pad 46. This structure allows the source connection electrodes 42E, the drain connection electrodes 44E, and the gate connection electrodes 46E to be formed integrally with the source pad 42, the drain pad 44, and the gate pad 46, respectively.

(1-14) The source connection electrodes 42E and the drain connection electrodes 44E may each be a plug electrode formed from a material that differs from that of the source pad 42 and the drain pad 44. An example of the material is tungsten. With this structure, the plug electrodes (the source connection electrodes 42E and the drain connection electrodes 44E) may have a flat upper surface, on which the source pad 42 and the drain pad 44 are arranged. This avoids wiring breakage caused by steps, thereby reducing wiring resistance.

### Second Embodiment

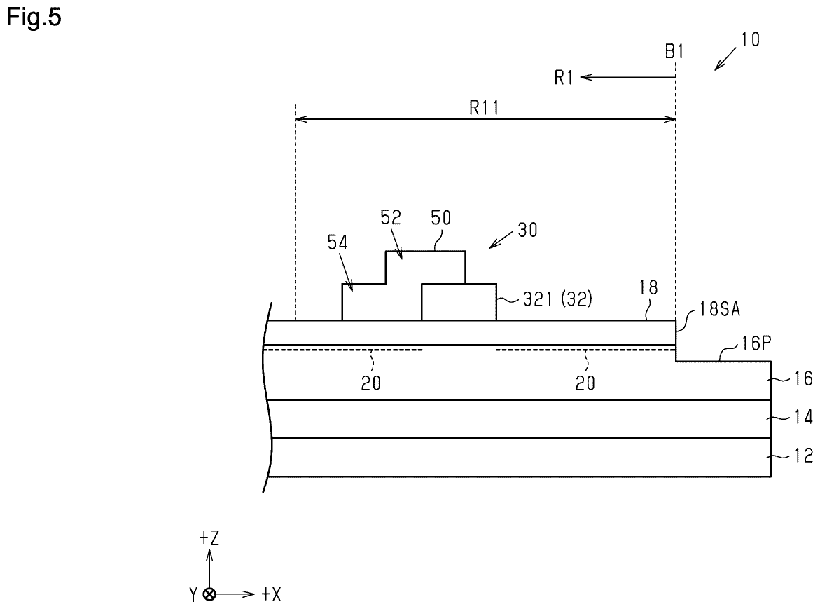

FIG. 5 is a schematic cross-sectional view showing an exemplary semiconductor device 10 according to a second embodiment. In FIG. 5, the same reference characters are given to those components that are the same as the corresponding components of the semiconductor device 10 in the first embodiment. Such components will not be described in detail below. Components differing from those of the first embodiment will be described.

As shown in FIG. 5, in the second embodiment, a first shield electrode 50 is used instead of the first shield electrode 34 of the guard ring 30 (refer to FIGS. 2 and 4) of the first embodiment. In the second embodiment, the wiring electrode 48 (refer to FIG. 3) and the guard ring connection electrode 48E of the first embodiment are omitted. The joint 49 is also omitted. Although not shown in plan view, the first shield electrode 50 is annularly arranged along the guard ring 30.

The first shield electrode 50 includes a first electrode part 52 arranged on the shield portion 32 (e.g., p-type GaN layer) and a second electrode part 54 arranged on the electron supply layer 18 and formed integrally with the first electrode part 52. Thus, the first shield electrode 50 is arranged on both the shield portion 32 and the electron supply layer 18. In the example shown in FIG. 5, the first shield electrode 50 is formed in a stepped manner. However, the first shield electrode 50 is not limited to a particular shape.

The first shield electrode 50, the source electrode 22, and the drain electrode 24 are formed from the same material. In an example, the first shield electrode 50 is formed of the combination of a Ti layer and an Al layer. Thus, the first shield electrode 50 is in ohmic contact with the 2DEG 20 present immediately below the electron supply layer 18. When the shield portion 32 is a p-type GaN layer, the combination of a Ti layer and an Al layer has a lower Schottky barrier height than TiN or the like. This allows for ohmic contact of the first shield electrode 50 with the shield portion 32.

In the second embodiment, the first shield electrode 50 is electrically connected to the 2DEG 20 present adjacent to the inner edge of the guard ring 30 in plan view. As described in the first embodiment, this 2DEG 20 has a source potential. Thus, the first shield electrode 50 has substantially the same potential as the 2DEG 20. In this structure, in the same manner as the first embodiment, the 2DEG 20 present immediately below the guard ring 30 (the shield portion 32) is depleted (is no longer present) and maintains the depletion state.

The semiconductor device 10 of the second embodiment has the following advantages in addition to the advantages (1-1) to (1-13) of the first embodiment.

(2-1) The first shield electrode 50, the source electrode 22, and the drain electrode 24 are formed from the same material. The first shield electrode 50 includes the first electrode part 52, which is in ohmic contact with the shield portion 32, and the second electrode part 54, which is formed integrally with the first electrode part 52 and in ohmic contact with the 2DEG 20. In this structure, the potential of the first shield electrode 50 is further appropriately maintained by the potential (source potential) of the 2DEG 20 present adjacent to the first shield electrode 50. Thus, the depletion (non-presence) of the 2DEG 20 present immediately below the guard ring 30 (the shield portion 32) is further appropriately maintained.

(2-2) The first shield electrode 50 is arranged on both the shield portion 32 and the electron supply layer 18. This allows for omission of the wiring structure of the guard ring 30 including the wiring electrode 48 and the guard ring connection electrodes 48E, which are arranged in the first embodiment. Since the wiring structure of the guard ring 30 is omitted, the width (in FIG. 1, shield widths W3 and W4) of the shield portion 32 of the guard ring 30 may be reduced as long as the surge resistance is sufficiently obtained. Thus, the chip area is reduced.

### Third Embodiment

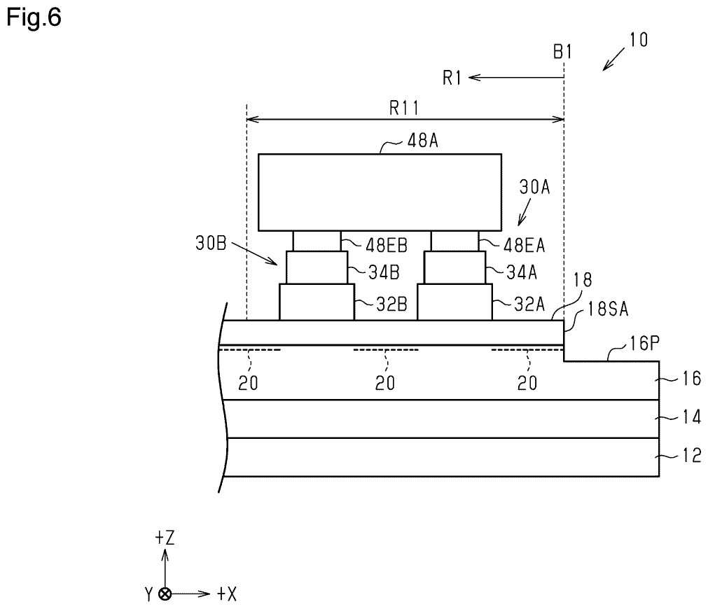

FIG. 6 is a schematic cross-sectional view showing an exemplary semiconductor device 10 according to a third embodiment. In FIG. 6, the same reference characters are given to those components that are the same as the corresponding components of the semiconductor device 10 in the first embodiment. Such components will not be described in detail below. Components differing from those of the first embodiment will be described.

As shown in FIG. 6, in the third embodiment, two guard rings 30A and 30B, which have the same structure as the guard ring 30 of the first embodiment, are arranged in the element region R1. Although not shown in plan view, the guard rings 30A and 30B are annularly arranged to surround the active region of the element region R1 in the same manner as the guard ring 30.

The guard ring 30A is located toward the boundary B1 in the peripheral part R11 of the element region R1. The guard ring 30A includes a shield portion 32A arranged on the electron supply layer 18 and a first shield electrode 34A arranged on the shield portion 32A. The first shield electrode 34A is connected to a wiring electrode 48A by a guard ring connection electrode 48EA. The shield portion 32A, the first shield electrode 34A, and the guard ring connection electrode 48EA of the guard ring 30A have the same structure as the shield portion 32, the first shield electrode 34, and the guard ring connection electrode 48E of the guard ring 30. The wiring electrode 48A of the third embodiment has a greater width than the wiring electrode 48 of the first embodiment.

The guard ring 30B is arranged adjacent to the guard ring 30A in a position of the peripheral part R11 of the element region R1 closer to the active region than the guard ring 30A is. The guard ring 30B includes a shield portion 32B arranged on the electron supply layer 18 and a first shield electrode 34B arranged on the shield portion 32B. The first shield electrode 34B is connected to a wiring electrode 48A by a guard ring connection electrode 48EB. The shield portion 32B, the first shield electrode 34B, and the guard ring connection electrode 48EB of the guard ring 30B have the same structure as the shield portion 32, the first shield electrode 34, and the guard ring connection electrode 48E of the guard ring 30.

The semiconductor device 10 of the third embodiment has the following advantages in addition to the advantages (1-1) to (1-13) of the first embodiment.

(3-1) The semiconductor device 10 includes multiple (for example, two in the third embodiment) guard rings 30A and 30B that are annularly arranged next to each other in the peripheral part R11 of the element region R1. In this structure, the depletion region of the 2DEG 20 is enlarged by the guard rings 30A and 30B. This further improves surge resistance.

### Fourth Embodiment

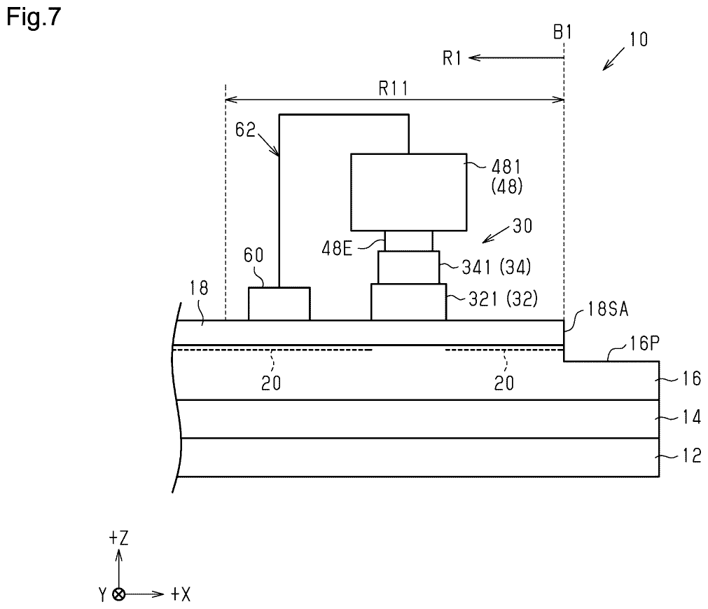

FIG. 7 is a schematic cross-sectional view showing an exemplary semiconductor device 10 according to a fourth embodiment. In FIG. 7, the same reference characters are given to those components that are the same as the corresponding components of the semiconductor device 10 in the first embodiment. Such components will not be described in detail below. Components differing from those of the first embodiment will be described.

As shown in FIG. 7, in the fourth embodiment, in addition to the first shield electrode 34 of the guard ring 30 of the first embodiment, a second shield electrode 60 is arranged in the peripheral part R11 of the element region R1 and is electrically connected to the first shield electrode 34. In the example shown in FIG. 7, the second shield electrode 60 is connected to the wiring electrode 48 by a connection wire 62. Although not shown in plan view, the second shield electrode 60 is annularly arranged to surround the active region of the element region R1 in the same manner as the first shield electrode 34 (the guard ring 30). In an example, the second shield electrode 60, the source electrode 22, and the drain electrode 24 may be formed from the same material. In an example, the first shield electrode 50 is formed of the combination of a Ti layer and an Al layer. The second shield electrode 60 is an example of a second electrode.

The second shield electrode 60 is arranged on the electron supply layer 18 between the shield portion 32 and the FET in plan view and is electrically connected to the 2DEG 20 present immediately below the second shield electrode 60. The 2DEG 20 described above is located adjacent to the inner edge of the guard ring 30 in plan view and has a source potential. Thus, the first shield electrode 50 has substantially the same potential as the 2DEG 20. In this structure, in the same manner as the first embodiment, the 2DEG 20 present immediately below the guard ring 30 (the shield portion 32) is depleted (is no longer present) and maintains the depletion state.

The semiconductor device 10 of the fourth embodiment has the following advantages in addition to the advantages (1-1) to (1-13) of the first embodiment.

(4-1) The second shield electrode 60 is arranged in addition to the first shield electrode 34. The second shield electrode 60 is electrically connected to the 2DEG 20 that is located adjacent to the inner edge of the guard ring 30 in plan view. The second shield electrode 60 is also electrically connected to the first shield electrode 34. In this structure, with the second shield electrode 60, the potential of the first shield electrode 50 is further appropriately maintained by the potential (source potential) of the 2DEG 20 present adjacent to the second shield electrode 60. Thus, the depletion (non-presence) of the 2DEG 20 present immediately below the guard ring 30 (the shield portion 32) is further appropriately maintained.

### Fifth Embodiment

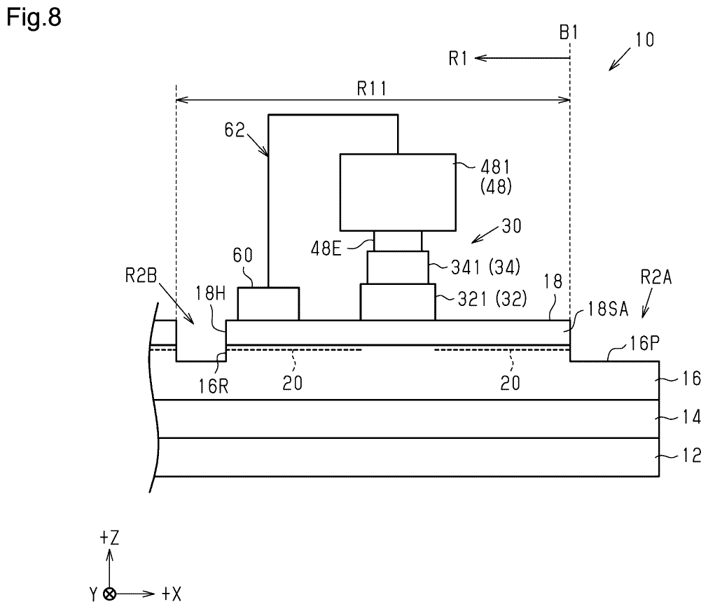

FIG. 8 is a schematic cross-sectional view showing an exemplary semiconductor device 10 according to a fifth embodiment. In FIG. 8, the same reference characters are given to those components that are the same as the corresponding components of the semiconductor device 10 in the first and fourth embodiments. Such components will not be described in detail below. Components differing from those of the first and fourth embodiments will be described.

As shown in FIG. 8, in the fifth embodiment, the element separation region R2 is arranged as a first element separation region R2A. In addition, a second element separation region R2B is arranged in the peripheral part R11 of the element region R1 between the second shield electrode 60 and the source electrodes 22A and 22D (refer to FIG. 1) located adjacent to the second shield electrode 60. The second element separation region R2B is defined by a hole 18H extending through the electron supply layer 18 and a groove 16R in the electron transit layer 16. With this structure, the 2DEG 20 is disconnected in the second element separation region R2B. Thus, the 2DEG 20 present adjacent to the inner edge of the guard ring 30 has a floating potential. The first shield electrode 34, which is electrically connected to the second shield electrode 60, maintains the same potential as the 2DEG 20 having a floating potential.

The semiconductor device 10 of the fifth embodiment has the following advantages in addition to the advantages (1-1) to (1-13) of the first embodiment.

(5-1) The 2DEG 20 is disconnected in the second element separation region R2B. This improves surge resistance. Since the 2DEG 20 is disconnected in the second element separation region R2B, the first shield electrode 34, which is electrically connected to the second shield electrode 60, maintains the same potential as the 2DEG 20 having a floating potential. The potential of the 2DEG 20 having a source potential may vary to, for example, a positive value in accordance with operation of the HEMT. In this regard, in the fifth embodiment, the first shield electrode 34 maintains the same potential as the 2DEG 20 having the floating potential. Thus, the 2DEG 20 present immediately below the guard ring 30 is further appropriately depleted.

### Modified Examples

The embodiments described above may be modified as follows. The embodiments described above and the modified examples described below can be combined as long as the combined modifications remain technically consistent with each other.

The semiconductor device 10 is not limited to a HEMT that uses GaN and may be configured as a HEMT that uses another one of the group III-V semiconductors.

In the element separation region R2, only the electron supply layer 18 may be removed. More specifically, the main surface (upper surface) of the electron transit layer 16 is completely or substantially flush in the element region R1 and the element separation region R2. When the electron supply layer 18 is removed from the element separation region R2, the 2DEG 20 is not generated in the electron transit layer 16 in the element separation region R2. Thus, the same advantages as those in the above embodiments are obtained.

The electron supply layer 18 and the electron transit layer 16 may be removed from the element separation region R2 so that the buffer layer 14 is exposed in the element separation region R2. The electron supply layer 18, the electron transit layer 16, and a portion of the buffer layer 14 (surface of a peripheral part of the buffer layer 14) may be removed from the element separation region R2.

In the embodiments, the number of HEMTs formed in the element region R1 (active region) is not particularly limited. The number of source electrodes 22, the number of drain electrodes 24, and the number of gate portions 26, and the number of gate electrodes 28 are not limited to those of the embodiments.

In the embodiments, the source pad 42 may be partially arranged in the active region. Alternatively, the drain pad 44 may be partially arranged in the active region. Alternatively, the gate pad 46 may be partially arranged in the active region.

In the present disclosure, the term “on” includes the meaning of “above” in addition to the meaning of “on” unless otherwise clearly indicated in the context. Therefore, the phrase “first layer formed on second layer” is intended to mean that the first layer may be formed on the second layer in contact with the second layer in one embodiment and that the first layer may be located above the second layer without contacting the second layer in another embodiment. In other words, the term “on” does not exclude a structure in which another layer is formed between the first layer and the second layer. For example, the above embodiments in which the electron supply layer 18 is formed on the electron transit layer 16 includes a structure in which an intermediate layer is disposed between the electron supply layer 18 and the electron transit layer 16 to stably form the 2DEG 20.

The Z-axis direction as referred to in the present disclosure does not necessarily have to be the vertical direction and does not necessarily have to fully conform to the vertical direction. In the structures according to the present disclosure (e.g., the structure shown in FIG. 1), “upward” and “downward” in the Z-axis direction as referred to in the present description are not limited to “upward” and “downward” in the vertical direction. For example, the X-axis direction may conform to the vertical direction. The Y-axis direction may conform to the vertical direction.

The directional terms used in the present disclosure such as “vertical,” “horizontal,” “above,” “below,” “top,” “bottom,” “frontward,” “backward,” “lateral,” “left,” “right,” “front,” and “back” will depend upon a particular orientation of the device being described and illustrated. The present disclosure may include various alternative orientations. Therefore, the directional terms should not be narrowly construed.

### Clauses

The technical aspects that are understood from the embodiments and the modified examples will be described below. The reference signs of the components in the embodiments are given to the corresponding components in clauses with parentheses. The reference signs are used as examples to facilitate understanding, and the components in each clause are not limited to those components given with the reference signs.

A1. A semiconductor device (10), including:
a substrate (12);
a first semiconductor layer (16) arranged above the substrate (12);
a second semiconductor layer (18) arranged on the first semiconductor layer (16) to generate a two-dimensional electronic gas (2DEG) in the first semiconductor layer (16) in a vicinity of an interface between the second semiconductor layer (18) and the first semiconductor layer (16);
a source electrode (22) and a drain electrode (24) arranged on the second semiconductor layer (18) and electrically connected to the 2DEG (20);
a third semiconductor layer (26) arranged on the second semiconductor layer (18) between the source electrode (22) and the drain electrode (24) and including an acceptor impurity;
a gate electrode (28) arranged on the third semiconductor layer (26); and
a guard ring (30) arranged on the second semiconductor layer (18), in which
the second semiconductor layer (18) defines a boundary (B1) between an element region (R1) in which a field-effect transistor (FET) is formed and an element separation region (R2) surrounding the element region (R1),
the FET is formed of the first semiconductor layer (16), the second semiconductor layer (18), the third semiconductor layer (26), the gate electrode (28), the source electrode (22), and the drain electrode (24), and
the guard ring (30) is arranged in a peripheral part (R11) of the element region (R1) and includes
   a fourth semiconductor layer (32) arranged on the second semiconductor layer (18) and including an acceptor impurity, and
   a first electrode (34) arranged on the fourth semiconductor layer (32) and electrically connected to the source electrode (22) or the 2DEG (20).

A2. The semiconductor device (10) according to clause A1, in which the first electrode (34) is electrically connected to the 2DEG (20) located adjacent to an inner edge of the guard ring (30) in plan view.

A3. The semiconductor device (10) according to clause A1 or A2, in which
the element separation region (R2) includes the substrate (12) and the first semiconductor layer (16), and
the second semiconductor layer (18) is removed from the element separation region (R2).

A4. The semiconductor device (10) according to clause A3, in which the first semiconductor layer (16) and the substrate (12) are cut at the element separation region (R2).

A5. The semiconductor device (10) according to any one of clauses A1 to A4, in which
the first semiconductor layer (16) includes GaN, and
the second semiconductor layer (18) includes AlGaN.

A6. The semiconductor device (10) according to any one of clauses A1 to A5, in which the drain electrode (24) is surrounded by the third semiconductor layer (26) in plan view.

A7. The semiconductor device (10) according to any one of clauses A1 to A6, in which the source electrode (22), the gate electrode (28), and the drain electrode (24) are repeatedly arranged in a first direction (X) so that the source electrode (22), the gate electrode (28), and the drain electrode (24) are separated and adjacent to each other in the first direction (X) in plan view and the gate electrode (28) is located between the source electrode (22) and the drain electrode (24).

A8. The semiconductor device (10) according to clause A7, in which the guard ring (30) is located adjacent to the source electrode (22A; 22D) in the first direction (X).

A9. The semiconductor device (10) according to clause A8, in which the 2DEG (20) extending in the first semiconductor layer (16) between the source electrode (22A; 22D) and the guard ring (30) located adjacent to the source electrode (22A; 22D) has a source potential.

A10. The semiconductor device (10) according to any one of clauses A1 to A9, in which the fourth semiconductor layer (32) has a width (W3) that is greater than a width (W1) of the third semiconductor layer (26) in the first direction (X).

A11. The semiconductor device (10) according to any one of clauses A1 to A10, in which the substrate (12) is electrically conductive and is set to be equal in potential to the source electrode (22).

A12. The semiconductor device (10) according to any one of clauses A1 to A11, in which the FET is of a normally-off type.

A13. The semiconductor device (10) according to any one of clauses A1 to A12, in which the first electrode (34) and the gate electrode (28) are formed from a same material.

A14. The semiconductor device (10) according to any one of clauses A1 to A12, in which the first electrode (34), the source electrode (22), and the drain electrode (24) are formed from a same material.

A15. The semiconductor device (10) according to clause A14, in which the first electrode (50) includes a first electrode part (52) arranged on the fourth semiconductor layer (32), and a second electrode part (54) arranged on the second semiconductor layer (18) and formed integrally with the first electrode part (52).

A16. The semiconductor device (10) according to any one of clauses A1 to A15, in which the guard ring (30) is one of guard rings (30A, 30B) arranged on the second semiconductor layer (18) in the peripheral part (R11) of the element region (R1).

A17. The semiconductor device (10) according to any one of clauses A1 to A16, further including:
a second electrode (60) arranged on the second semiconductor layer (18) between the fourth semiconductor layer (32) and the FET in plan view and electrically connected to the 2DEG (20) located immediately below the second electrode (60),
in which the second electrode (60) is electrically connected to the first electrode (34).

A18. The semiconductor device (10) according to clause A17, in which the second electrode (60) is located adjacent to the source electrode (22A; 22D) of the FET, and the element separation region (R2) includes a first element separation region (R2A), the semiconductor device (10), further including:
a second element separation region (R2B) formed between the second electrode (60) and the source electrode (22A; 22D).

A19. The semiconductor device (10) according to any one of clauses A1 to A18, further including:
a source pad (42) connected to the source electrode (22);
a drain pad (44) connected to the drain electrode (24); and
a gate pad (46) connected to the gate electrode (28), in which
at least a portion of the source pad (42), at least a portion of the drain pad (44), or at least a portion of the gate pad (46) is present in an active region surrounded by the peripheral part (R11) of the element region (R1) in plan view.

A20. The semiconductor device (10) according to clause A19, in which at least a portion of the source pad (42) and at least a portion of the drain pad (44) are present in the active region in plan view, the semiconductor device (10) further including:
a source connection electrode (42E) formed from a material that differs from that of the source pad (42) and connecting at least a portion of the source pad (42) and the source electrode (22); and
a drain connection electrode (44E) formed from a material that differs from that of the drain pad (44) and connecting at least a portion of the drain pad (44) and the drain electrode (24).

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A semiconductor device, comprising:
a substrate;
a first semiconductor layer arranged above the substrate;
a second semiconductor layer arranged on the first semiconductor layer to generate a two-dimensional electronic gas in the first semiconductor layer in a vicinity of an interface between the second semiconductor layer and the first semiconductor layer;
a source electrode and a drain electrode arranged on the second semiconductor layer and electrically connected to the two-dimensional electronic gas;
a third semiconductor layer arranged on the second semiconductor layer between the source electrode and the drain electrode and including an acceptor impurity;
a gate electrode arranged on the third semiconductor layer; and
a guard ring arranged on the second semiconductor layer, wherein
the second semiconductor layer defines a boundary between an element region in which a field-effect transistor is formed and an element separation region surrounding the element region,
the field-effect transistor is formed of the first semiconductor layer, the second semiconductor layer, the third semiconductor layer, the gate electrode, the source electrode, and the drain electrode, and
the guard ring is arranged in a peripheral part of the element region and includes
a fourth semiconductor layer arranged on the second semiconductor layer and including an acceptor impurity, and
a first electrode arranged on the fourth semiconductor layer and electrically connected to the source electrode or the two-dimensional electronic gas.

2. The semiconductor device according to claim 1, wherein the first electrode is electrically connected to the two-dimensional electronic gas located adjacent to an inner edge of the guard ring in plan view.

3. The semiconductor device according to claim 1, wherein
the element separation region includes the substrate and the first semiconductor layer, and
the second semiconductor layer is removed from the element separation region.

4. The semiconductor device according to claim 3, wherein the first semiconductor layer and the substrate are cut at the element separation region.

5. The semiconductor device according to claim 1, wherein
the first semiconductor layer includes GaN, and
the second semiconductor layer includes AlGaN.

6. The semiconductor device according to claim 1, wherein the drain electrode is surrounded by the third semiconductor layer in plan view.

7. The semiconductor device according to claim 1, wherein the source electrode, the gate electrode, and the drain electrode are repeatedly arranged in a first direction so that the source electrode, the gate electrode, and the drain electrode are separated and adjacent to each other in the first direction in plan view and the gate electrode is located between the source electrode and the drain electrode.

8. The semiconductor device according to claim 7, wherein the guard ring is located adjacent to the source electrode in the first direction.

9. The semiconductor device according to claim 8, wherein the two-dimensional electronic gas extending in the first semiconductor layer between the source electrode and the guard ring located adjacent to the source electrode has a source potential.

10. The semiconductor device according to claim 1, wherein the fourth semiconductor layer has a width that is greater than a width of the third semiconductor layer in the first direction.

11. The semiconductor device according to claim 1, wherein the substrate is electrically conductive and is set to be equal in potential to the source electrode.

12. The semiconductor device according to claim 1, wherein the field-effect transistor is of a normally-off type.

13. The semiconductor device according to claim 1, wherein the first electrode and the gate electrode are formed from a same material.

14. The semiconductor device according to claim 1, wherein the first electrode, the source electrode, and the drain electrode are formed from a same material.

15. The semiconductor device according to claim 14, wherein the first electrode includes
a first electrode part arranged on the fourth semiconductor layer, and
a second electrode part arranged on the second semiconductor layer and formed integrally with the first electrode part.

16. The semiconductor device according to claim 1, wherein the guard ring is one of guard rings arranged on the second semiconductor layer in the peripheral part of the element region.

17. The semiconductor device according to claim 1, further comprising:
a second electrode arranged on the second semiconductor layer between the fourth semiconductor layer and the field-effect transistor in plan view and electrically connected to the two-dimensional electronic gas located immediately below the second electrode,
wherein the second electrode is electrically connected to the first electrode.

18. The semiconductor device according to claim 17, wherein the second electrode is located adjacent to the source electrode of the field-effect transistor, and the element separation region includes a first element separation region, the semiconductor device further comprising:
a second element separation region formed between the second electrode and the source electrode.

19. The semiconductor device according to claim 1, further comprising:
a source pad connected to the source electrode;
a drain pad connected to the drain electrode; and
a gate pad connected to the gate electrode, wherein
at least a portion of the source pad, at least a portion of the drain pad, or at least a portion of the gate pad is present in an active region surrounded by the peripheral part of the element region in plan view.

20. The semiconductor device according to claim 19, wherein at least a portion of the source pad and at least a portion of the drain pad are present in the active region in plan view, the semiconductor device further comprising:
a source connection electrode formed from a material that differs from that of the source pad and connecting at least a portion of the source pad and the source electrode; and
a drain connection electrode formed from a material that differs from that of the drain pad and connecting at least a portion of the drain pad and the drain electrode.
